(19) United States
(12) Patent Application Publication
(10) Pub. No.: US 2025/0029933 A1
(43) Pub. Date: Jan. 23, 2025

(54) ELECTRONIC DEVICE

(71) Applicant: Renesas Electronics Corporation, Tokyo (JP)

(72) Inventors: Ryuichi OIKAWA, Tokyo (JP); Shuuichi KARIYAZAKI, Tokyo (JP)

(21) Appl. No.: 18/770,072

(22) Filed: Jul. 11, 2024

(30) Foreign Application Priority Data
Jul. 18, 2023 (JP) 2023-116556

(51) Int. Cl. H01L 23/538; H01L 23/00; H01L 25/065; H10B 80/00

(52) U.S. Cl. CPC H01L 23/5386; H01L 25/0655; H01L 24/16; H01L 2224/16227; H10B 80/00

(57) ABSTRACT

The performance of an electronic device can be improved. The electronic device includes a wiring substrate, a semiconductor memory device disposed on the wiring substrate, and a semiconductor control device disposed on the wiring substrate. The wiring substrate includes a first fixed potential wiring and a second fixed potential wiring, and a plurality of signal wirings arranged between the first fixed potential wiring and the second fixed potential wiring. The plurality of signal wirings includes a first signal wiring adjacent to the first fixed potential wiring, a second signal wiring adjacent to the first signal wiring, and a third signal wiring adjacent to the second signal wiring. A first distance between the first signal wiring and the second signal wiring is smaller than a second distance between the second signal wiring and the third signal wiring.

### CROSS-REFERENCE TO RELATED APPLICATIONS

The disclosure of Japanese Patent Application No. 2023-116556 filed on Jul. 18, 2023, including the specification, drawings and abstract is incorporated herein by reference in its entirety.

### BACKGROUND

The present invention relates to an electronic device, for example, it can be suitably used for an electronic device including a plurality of semiconductor devices and a wiring substrate.

There are disclosed techniques listed below.

[Patent Document 1] Japanese Unexamined Patent Application Publication No. 2006-237385

Patent Document 1 discloses a technology related to a semiconductor device in which a plurality of semiconductor memory devices and a semiconductor data processing device that controls the plurality of semiconductor memory devices are on a mounting substrate.

### SUMMARY

The present inventors have considered arranging a plurality of signal wirings evenly so that crosstalk becomes even. On the other hand, in recent years, there is also a demand for cost reduction of an electronic device. Therefore, the present inventors have considered reducing the number of wiring layers of the wiring substrate to be used. As a result, it is necessary to secure a region (space) for arranging other wirings provided on other wiring layers on the wiring layer where these signal wirings are provided. As a countermeasure, the present inventors have considered further reducing the distance (pitch) between adjacent wirings. However, according to the study of the present inventors, when a plurality (3 or more) of signal wirings is arranged evenly, it was found that a signal propagating a certain signal wiring is easily affected by a signal propagating a signal wiring located not next to this signal wiring but two or more next to it. That is, there is a risk that timing fluctuation due to signal interference will increase. This is because it leads to a decrease in the performance of the electronic device, and it is desirable to take measures.

Other objects and novel features will become apparent from the description of this specification and the accompanying drawings.

According to one embodiment, an electronic device includes a wiring substrate, a first semiconductor device disposed on the wiring substrate, and a second semiconductor device disposed on the wiring substrate and controlling the first semiconductor device. The wiring substrate includes a first fixed potential wiring, a second fixed potential wiring, and a plurality of signal wirings arranged between the first fixed potential wiring and the second fixed potential wiring in plan view. The plurality of signal wirings includes a first signal wiring adjacent to the first fixed potential line, a second signal wiring adjacent to the first signal wiring, and a third signal wiring adjacent to the second signal wiring. A first distance between the first signal wiring and the second signal wiring is smaller than a second distance between the second signal wiring and the third signal wiring.

According to one embodiment, the performance of the electronic device can be improved.

### BRIEF DESCRIPTION OF THE DRAWINGS

FIG. 1 is a plan view schematically showing an electronic device according to a first embodiment.

FIG. 2 is a cross-sectional view of a main portion of the electronic device according to the first embodiment.

FIG. 3 is a partial enlarged plan view of a wiring region of a wiring substrate used in the electronic device according to the first embodiment.

FIG. 4 is a partial enlarged plan view of a wiring region of the wiring substrate used in the electronic device according to the first embodiment.

FIG. 5 is a partial enlarged plan view of a wiring region of the wiring substrate used in the electronic device according to the first embodiment.

FIG. 6 is a partial enlarged plan view of a wiring region of the wiring substrate used in the electronic device according to the first embodiment.

FIG. 7 is a plan view of a main portion of a wiring substrate according to a first examined example.

FIG. 8 is a plan view of a main portion of a wiring substrate according to a second examined example.

FIG. 9 is an explanatory diagram for explaining a timing variation caused by a crosstalk.

FIG. 10 is a graph showing an example of a timing margin when a write operation of a semiconductor memory device is performed by a semiconductor control device.

FIG. 11 is a graph showing an example of a timing margin when a read operation of the semiconductor memory device is performed by the semiconductor control device.

FIG. 12 is a partial enlarged plan view of a wiring region of a wiring substrate used in an electronic device according to a second embodiment.

FIG. 13 is a partial enlarged plan view of a wiring region of a wiring substrate used in the electronic device according to the second embodiment.

### DETAILED DESCRIPTION

In the following embodiments, when required for convenience, the description will be made by dividing into a plurality of sections or embodiments, but except when specifically stated, they are not independent of each other, and one is related to the modified example, detail, supplementary description, or the like of part or all of the other. In the following embodiments, the number of elements, etc. (including the number of elements, numerical values, quantities, ranges, etc.) is not limited to the specific number, but may be not less than or equal to the specific number, except for cases where the number is specifically indicated and is clearly limited to the specific number in principle. Furthermore, in the following embodiments, it is needless to say that the constituent elements (including element steps and the like) are not necessarily essential except in the case where they are specifically specified and the case where they are considered to be obviously essential in principle. Similarly, in the following embodiments, when referring to the shapes, positional relationships, and the like of components and the like, it is assumed that the shapes and the like are substantially approximate to or similar to the Shapes and the like, except for the case in which they are specifically specified and the case in which they are considered to be obvious in principle, and the like. The same applies to the above numerical values and ranges.

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the drawings used in the embodiments, hatching may be omitted even in the case of cross-sectional view in order to make the drawings easier to see. Also, even in the case of a plan view, hatching may be used to make the drawing easier to see.

### First Embodiment

### <OVERALL CONFIGURATION OF ELECTRONIC DEVICE>

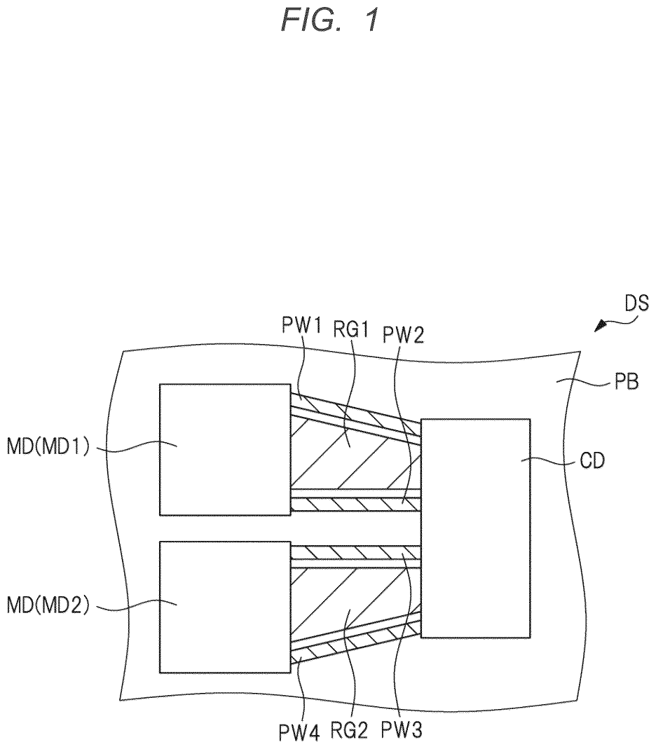

FIG. 1 is a plan view schematically showing an electronic device DS of the present embodiment.

As shown in FIG. 1, the electronic device DS of the present embodiment includes a wiring substrate (mounting substrate) PB, a memory (storage) semiconductor device (semiconductor memory device) MD mounted on the wiring substrate PB, and a control semiconductor device (semiconductor control device) CD mounted on the wiring substrate PB. Other electronic components (not shown) can also be mounted on the wiring substrate PB.

The semiconductor device MD is a semiconductor device that includes a memory chip (semiconductor chip for memory). In the present embodiment, a semiconductor package that packages the memory chip is applied as the semiconductor device MD. In another embodiment, a memory chip can be applied as the semiconductor device MD.

In the present embodiment, it is described when two semiconductor devices MD are mounted on a wiring substrate PB. One of the two semiconductor devices MD mounted on the wiring substrate PB is referred to as a semiconductor device MD1 hereinafter, and the other is referred to as a semiconductor device MD2 hereinafter. The semiconductor devices MD1 and MD2 can use semiconductor devices which are the same type (same configuration) as each other.

The semiconductor device CD is a semiconductor device that controls the semiconductor devices MD1 and MD2. In the present embodiment, the semiconductor device CD is a control chip (a semiconductor chip for control) that controls the semiconductor devices MD1 and MD2. That is, in the present embodiment, an unpackaged control chip (i.e., the control chip itself) is used as the semiconductor device CD. The control chip can be, for example, a System On Chip (SoC). In another embodiment, a semiconductor package that packages the control chip can also be applied as the semiconductor device CD.

The wiring substrate PB has the plurality of wirings that electrically connect the semiconductor control device CD and the semiconductor memory device MDI, the plurality of wirings that electrically connect the semiconductor control device CD and the semiconductor memory device MD2, and the plurality of power supply wirings PW1, PW2, PW3, PW4.

The wiring region RG1 shown in FIG. 1 is an area where the plurality of wirings that electrically connect the semiconductor control device CD and the semiconductor memory device MD1 are arranged. The plurality of (many) signal wirings and the plurality of ground wirings are arranged in the wiring region RG1. The wiring region RG2 shown in FIG. 1 is an area where the plurality of wirings that electrically connect the semiconductor control device CD and the semiconductor memory device MD2 are arranged. The plurality of (many) signal wirings and the plurality of ground wirings are arranged in the wiring region RG2. In the wiring substrate PB, the wiring area RGI is arranged between the semiconductor device CD and the semiconductor device MD1, and the wiring region RG2 is arranged between the semiconductor device CD and the semiconductor device MD2.

The power supply wirings PW1, PW2, PW3, PW4 are wires to which a power supply potential is supplied. In the wiring substrate PB, the power supply wirings PW1 and PW2 extend between the semiconductor device CD and the semiconductor device MD1 so as to sandwich the wiring region RG1. That is, in the wiring substrate PB, the wiring region RG1 is arranged between the power supply wirings PW1 and PW2.

In the wiring substrate PB, the power supply wirings PW3 and PW4 extend between the semiconductor device CD and the semiconductor device MD2 so as to sandwich the wiring region RG2. That is, in the wiring substrate PB, the wiring region RG2 is arranged between the power supply wirings PW3 and PW4.

The semiconductor control device CD is electrically connected to each of the power supply wirings PW1, PW2, PW3, PW4. The semiconductor memory device MD1 is electrically connected to each of the power supply wirings PW1, PW2. The semiconductor memory device MD2 is electrically connected to each of the power supply wirings PW3, PW4. This allows the power supply potential to be supplied to the semiconductor device CD from each of the power supply wirings PW1, PW2, PW3, PW4. The power supply potential can be supplied to the semiconductor device MD1 from each of the power supply wirings PW1, PW2. The power supply potential can be supplied to the semiconductor device MD2 from each of the power supply wirings PW3, PW4.

In the electronic device DS, since the semiconductor device CD, which is a semiconductor chip, and the plurality of semiconductor devices MD1, MD2 including a semiconductor chip not shown are mounted on the wiring substrate PB, the electronic device DS is considered to include a semiconductor chip. Therefore, the electronic device DS can also be considered as a semiconductor device.

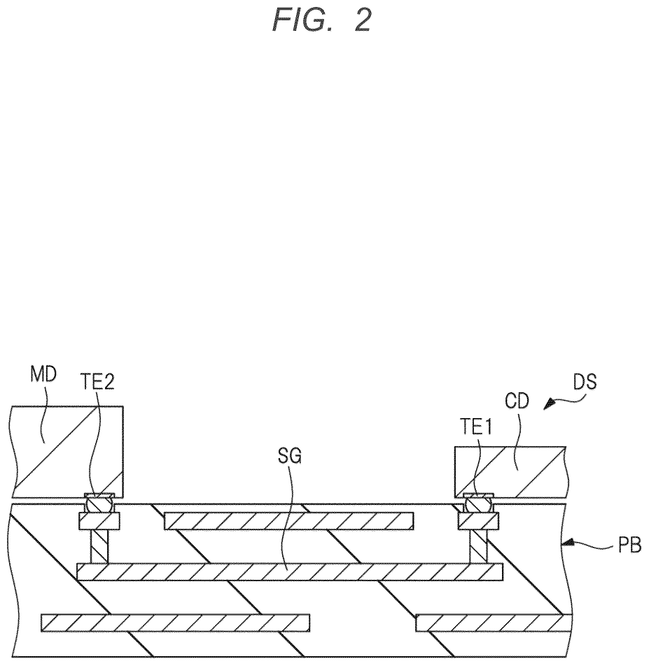

FIG. 2 is a cross-sectional view of the main portion of the electronic device DS. FIG. 2 shows a cross-section passing through the wiring region RG1 or RG2 shown in FIG. 1. If the cross-section in FIG. 2 passes through the wiring region RG1, the signal wiring SG shown in FIG. 2 is the signal wiring SG arranged in the wiring region RG1. If the cross-section in FIG. 2 passes through the wiring region RG2, the signal wiring SG shown in FIG. 2 is the signal wiring SG arranged in the wiring region RG2.

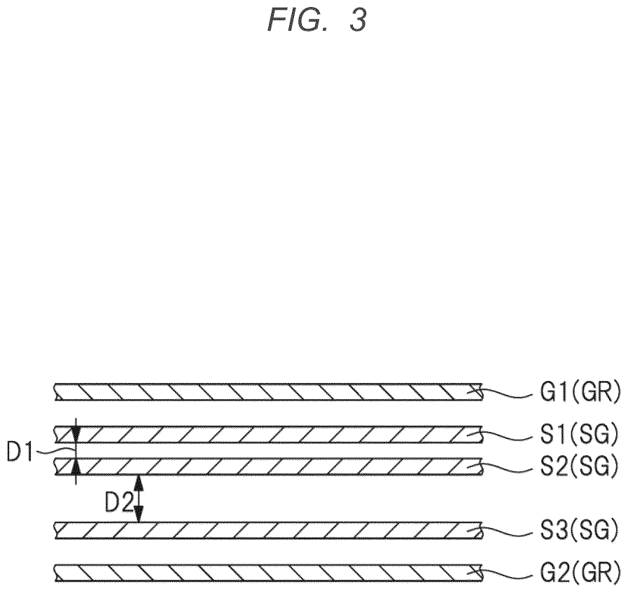

Each of FIGS. 3, 4, 5, and 6 is a partial enlarged view showing a part of the wiring region RG1 or the wiring region RG2 shown in FIG. 1.

Although details will be described later, the technical idea of the present embodiment is to arrange three or more signal wirings SG between the ground wiring G1 and the ground wiring G2, and to arrange these three or more signal wirings SG alternately with a small wiring interval and a larger wiring interval. FIGS. 3, 4, 5, and 6 follow this technical idea, but the number of signal wirings SG arranged between the ground wiring G1 and the ground wiring G2 differs from each other in FIGS. 3, 4, 5, and 6.

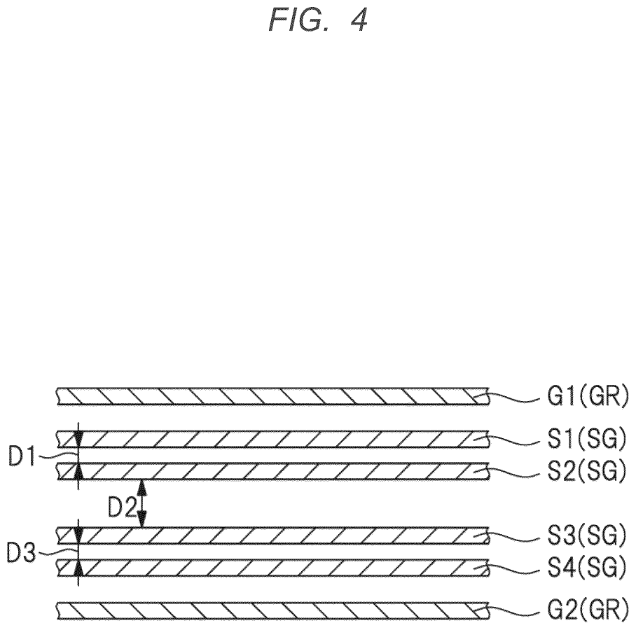

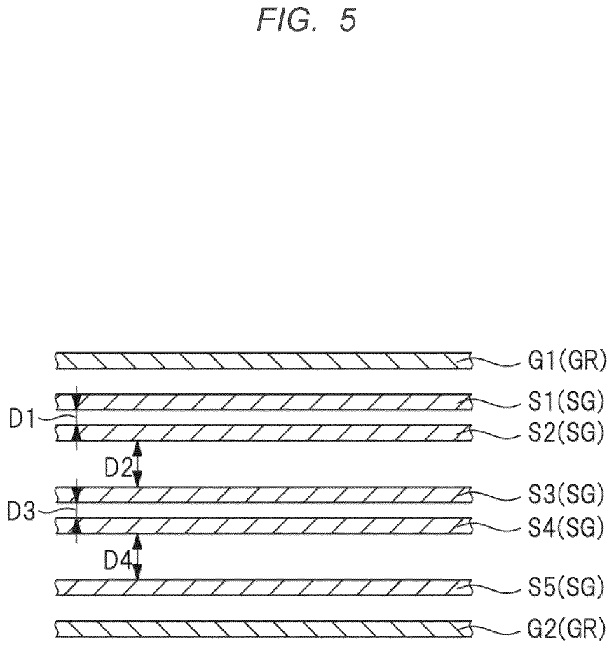

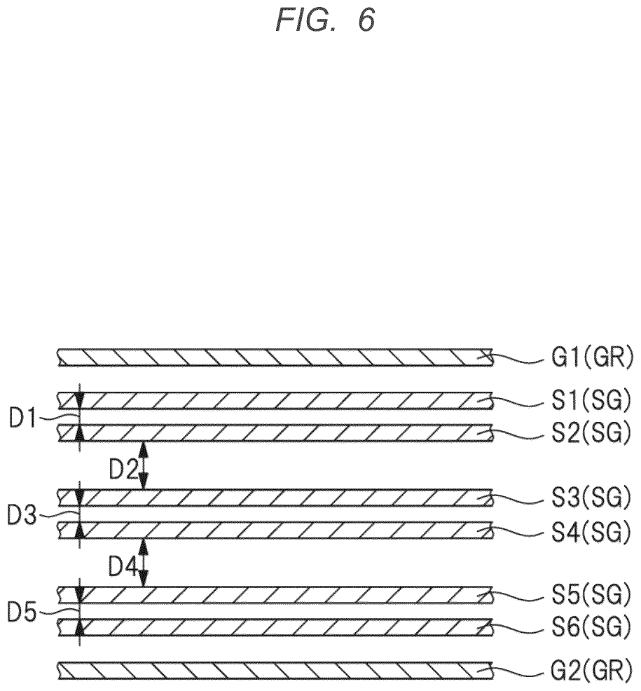

FIG. 3 shows two ground wirings GR and three signal wirings SG arranged between the two ground wirings GR in a plan view. FIG. 4 shows two ground wirings GR and four signal wirings SG arranged between the two ground wirings GR in a plan view. FIG. 5 shows two ground wirings GR and five signal wirings SG arranged between the two ground wirings GR in a plan view. FIG. 6 shows two ground wirings GR and six signal wirings SG arranged between the two ground wirings GR in a plan view. In each wiring region RG1, RG2 of FIG. 1, many signal wirings SG and ground wirings GR are arranged, and each of FIGS. 3, 4, 5, and 6 shows a part of many signal wirings SG and ground wirings GR arranged in the wiring region RG1 or the wiring region RG2.

The semiconductor device CD has a plurality of terminals (electrodes) TE1 (see FIG. 2). The semiconductor device MD has a plurality of terminals (electrodes) TE2 (see FIG. 2).

If each of FIGS. 3, 4, 5, and 6 is an enlarged view of a part of the wiring region RG1, one end of each signal wiring SG shown in FIGS. 3, 4, 5, and 6 is electrically connected to any of the plurality of terminals TE1 of the semiconductor device CD, and the other end of each signal wiring SG shown in FIGS. 3, 4, 5, and 6 is electrically connected to any of the plurality of terminals TE2 of the semiconductor device MD1. In this case, each signal wiring SG shown in FIGS. 3, 4, 5, and 6 functions as a signal wiring that electrically connects the semiconductor device CD and the semiconductor device MD1 and transmits signals between the semiconductor device CD and the semiconductor device MD1.

If each of FIGS. 3, 4, 5, and 6 is an enlarged view of a part of the wiring region RG2, one end of each signal wiring SG shown in FIGS. 3, 4, 5, and 6 is electrically connected to any of the plurality of terminals TE1 of the semiconductor device CD, and the other end of each signal wiring SG shown in FIGS. 3, 4, 5, and 6 is electrically connected to any of the plurality of terminals TE2 of the semiconductor device MD2. In this case, each signal wiring SG shown in FIGS. 3, 4, 5, and 6 functions as a signal wiring that electrically connects the semiconductor device CD and the semiconductor device MD2 and transmits signals between the semiconductor device CD and the semiconductor device MD2.

Signals can be transmitted from the semiconductor device CD to the semiconductor device MD1, or from the semiconductor device MD1 to the semiconductor device CD, through the plurality of signal wirings SG provided in the wiring region RG1. Signals can be transmitted from the semiconductor device CD to the semiconductor device MD2, or from the semiconductor device MD2 to the semiconductor device CD, through the plurality of signal wirings SG provided in the wiring region RG2. Note that each signal wiring SG shown in FIGS. 3, 4, 5, and 6 is a single-ended type signal wiring.

In the case where the wiring substrate PB has a plurality of wiring layers, ground wirings GR and signal wirings SG shown in each of FIGS. 3, 4, 5, and 6 are formed in any of the plurality of wiring layers of the wiring substrate PB.

Here, in each of FIGS. 3, 4, 5, and 6, one of the two ground wirings GR is referred to as a ground wiring G1, and the other of the two ground wirings GR is referred to as a ground wiring G2. The ground wiring G1 and the ground wiring G2 are separated from each other in plan view. In FIG. 3, the three signal wirings SG arranged between the ground wiring G1 and the ground wiring G2 are referred to as a signal wiring S1, a signal wiring S2, and a signal wiring S3 in the direction from the ground wiring G1 to the ground wiring G2. In FIG. 4, the four signal wirings SG arranged between the ground wiring G1 and the ground wiring G2 are referred to as a signal wiring S1, a signal wiring S2, a signal wiring S3, and a signal wiring S4 in the direction from the ground wiring G1 to the ground wiring G2. In FIG. 5, the five signal wirings SG arranged between the ground wiring G1 and the ground wiring G2 are referred to as a signal wiring S1, a signal wiring S2, a signal wiring S3, a signal wiring S4, and a signal wiring S5 in the direction from the ground wiring G1 to the ground wiring G2. In FIG. 6, the six signal wirings SG arranged between the ground wiring G1 and the ground wiring G2 are referred to as a signal wiring S1, a signal wiring S2, a signal wiring S3, a signal wiring S4, a signal wiring S5, and a signal wiring S6 in the direction from the ground wiring G1 to the ground wiring G2.

In the case of FIG. 3, the ground wiring G1, the signal wiring S1, the signal wiring S2, the signal wiring S3, and the ground wiring G2 are formed in the same layer (the same wiring layer) on the wiring substrate PB and are arranged and run parallel in this order in plan view. The same applies to the cases of FIGS. 4, 5, and 6, where the ground wiring G1, the signal wirings S1 to S4, S1 to S5, and S1 to S6, and the ground wiring G2 are formed in the same layer on the wiring substrate PB and are arranged and run parallel in this order in plan view. In each of FIGS. 3, 4, 5, and 6, the ground wiring G1 and the signal wiring S1 are adjacent to each other, the signal wiring S1 and the signal wiring S2 are adjacent to each other, and the signal wiring S2 and the signal wiring S3 are adjacent to each other. In each of FIGS. 3, 4, 5, and 6, the signal wiring S1 is arranged between the ground wiring G1 and the signal wiring S2, and the signal wiring S2 is arranged between the signal wiring S1 and the signal wiring S3.

In each of FIGS. 4, 5, and 6, the signal wiring S3 and the signal wiring S4 are adjacent to each other, and the signal wiring S3 is arranged between the signal wiring S2 and the signal wiring S4. In each of FIGS. 5 and 6, the signal wiring S4 and the signal wiring S5 are adjacent to each other, and the signal wiring S4 is arranged between the signal wiring S3 and the signal wiring S5. In FIG. 6, the signal wiring S5 and the signal wiring S6 are adjacent to each other, and the signal wiring S5 is arranged between the signal wiring S4 and the signal wiring S6.

In FIG. 3, the signal wiring S3 and the ground wiring G2 are adjacent to each other, and the signal wiring S3 is arranged between the signal wiring S2 and the ground wiring G2. In FIG. 4, the signal wiring S4 and the ground wiring G2 are adjacent to each other, and the signal wiring S4 is arranged between the signal wiring S3 and the ground wiring G2. In FIG. 5, the signal wiring S5 and the ground wiring G2 are adjacent to each other, and the signal wiring S5 is arranged between the signal wiring S4 and the ground wiring G2. In FIG. 6, the signal wiring S6 and the ground wiring G2 are adjacent to each other, and the signal wiring S6 is arranged between the signal wiring S5 and the ground wiring G2.

Note that two lines being adjacent to each other means that no other line is arranged between the two lines.

The ground wiring GR is a line to which a ground potential (reference potential) is supplied. The ground wiring G1 and the ground wiring G2 have the function of electromagnetically shielding the plurality of signal wirings SG arranged between the ground wiring G1 and the ground wiring G2 from the lines outside the ground wiring G1 and G2. In each of FIGS. 3, 4, 5, and 6, no ground wiring is arranged between the plurality of signal wirings SG arranged between the ground wiring G1 and the ground wiring G2.

Next, the spacing between the signal wirings SG in each of FIGS. 3, 4, 5, and 6 will be described.

Here, the distance (spacing) between the signal wiring S1 and the signal wiring S2 is referred to as a distance D1. The distance (spacing) between the signal wiring S2 and the signal wiring S3 is referred to as a distance D2. The distance (spacing) between the signal wiring S3 and the signal wiring S4 is referred to as a distance D3. The distance (spacing) between the signal wiring S4 and the signal wiring S5 is referred to as a distance D4. The distance (spacing) between the signal wiring S5 and the signal wiring S6 is referred to as a distance D5.

In each of FIGS. 3, 4, 5, and 6, the plurality of signal wirings SG arranged between the ground wiring G1 and the ground wiring G2 are not arranged at equal intervals.

Specifically, in the case of FIG. 3, the distance D1 between the signal wiring S1 and the signal wiring S2 is smaller than the distance D2 between the signal wiring S2 and the signal wiring S3 (i.e., “D2>D1”).

In the case of FIG. 4, the distance D1 between the signal wiring S1 and the signal wiring S2 is smaller than the distance D2 between the signal wiring S2 and the signal wiring S3, and the distance D3 between the signal wiring S3 and the signal wiring S4 is smaller than the distance D2 between the signal wiring S2 and the signal wiring S3 (i.e., “D2>D1” and “D2>D3”). It is preferable that the distance D1 between the signal wiring S1 and the signal wiring S2 and the distance D3 between the signal wiring S3 and the signal wiring S4 are the same as each other (i.e., “D1=D3”).

In the case of FIG. 5, the distance D1 between the signal wiring S1 and the signal wiring S2 is smaller than the distance D2 between the signal wiring S2 and the signal wiring S3, and is also smaller than the distance D4 between the signal wiring S4 and the signal wiring S5 (i.e., “D2>D1” and “D4>D1”). And, the distance D3 between the signal wiring S3 and the signal wiring S4 is smaller than the distance D2 between the signal wiring S2 and the signal wiring S3, and is also smaller than the distance D4 between the signal wiring S4 and the signal wiring S5 (i.e., “D2>D3” and “D4>D3”). It is preferable that the distance D1 between the signal wiring S1 and the signal wiring S2 and the distance D3 between the signal wiring S3 and the signal wiring S4 are the same as each other (i.e., “D1=D3”). It is preferable that the distance D2 between the signal wiring S2 and the signal wiring S3 and the distance D4 between the signal wiring S4 and the signal wiring S5 are the same as each other (i.e., “D2=D4”).

In the case of FIG. 6, the distance D1 between the signal wiring S1 and the signal wiring S2 is smaller than the distance D2 between the signal wiring S2 and the signal wiring S3, and is also smaller than the distance D4 between the signal wiring S4 and the signal wiring S5 (i.e., “D2>D1” and “D4>D1”). And, the distance D3 between the signal wiring S3 and the signal wiring S4 is smaller than the distance D2 between the signal wiring S2 and the signal wiring S3, and is also smaller than the distance D4 between the signal wiring S4 and the signal wiring S5 (i.e., “D2>D3” and “D4>D3”). And, the distance D5 between the signal wiring S5 and the signal wiring S6 is smaller than the distance D2 between the signal wiring S2 and the signal wiring S3, and is also smaller than the distance D4 between the signal wiring S4 and the signal wiring S5 (i.e., “D2>D5” and “D4>D5”). It is preferable that the distance D1 between the signal wiring S1 and the signal wiring S2, the distance D3 between the signal wiring S3 and the signal wiring S4, and the distance D5 between the signal wiring S5 and the signal wiring S6 are the same as each other (i.e., “D1=D3=D5”). It is preferable that the distance D2 between the signal wiring S2 and the signal wiring S3 and the distance D4 between the signal wiring S4 and the signal wiring S5 are the same as each other (i.e., “D2=D4”).

By setting such a wiring interval for the plurality of signal wirings SG arranged between the ground wiring G1 and the ground wiring G2, it is possible to suppress the area required to arrange these lines and to suppress timing variations (signal timing variations) caused by signal interference in each of the plurality of signal wirings SG. The reason for this will be explained in detail later.

The plurality of signal wirings SG (3 or more) arranged between the ground wirings G1, G2 according to the technical idea of the present embodiment exist in one or both of the wiring regions RG1, RG2 shown in FIG. 1. The number of signal wirings SG between the ground wirings G1, G2 is 3 in FIG. 3, 4 in FIG. 4, 5 in FIG. 5, and 6 in FIG. 6, but there may be 7 or more.

In the present embodiment, it has been described when two semiconductor devices MD (MD1, MD2) for memory and a semiconductor device CD for controlling these two semiconductor devices MD for memory are arranged on the wiring substrate PB, but the number of semiconductor devices MD for memory to be arranged on the wiring substrate PB is not limited to two. For example, it is possible to not mount the semiconductor device MD2 on the wiring substrate PB, and instead mount one semiconductor memory device MD (MD1) and a semiconductor device CD that controls the semiconductor memory device MD on the wiring substrate PB. Alternatively, it is possible to mount three or more semiconductor memory devices MD and a semiconductor device CD that controls the three or more semiconductor memory devices MD on the wiring substrate PB.

### <BACKGROUND OF STUDY>

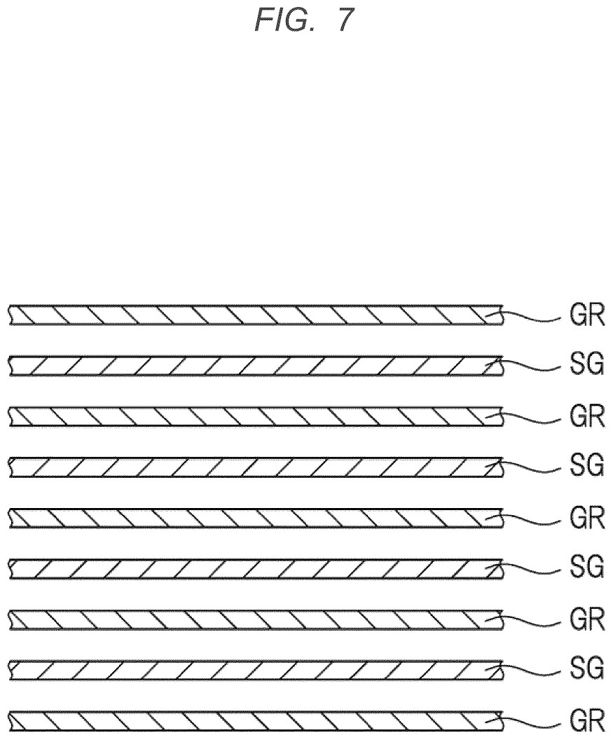

FIG. 7 is a plan view of the main portion of the wiring substrate of the first examined example studied by the present inventor, corresponding to FIGS. 3, 4, 5, and 6 of the present embodiment.

In the case of the first examined example in FIG. 7, signal wiring SG and ground wiring GR are alternately arranged. Therefore, each signal wiring SG is less likely to receive crosstalk from other signal wiring SG.

However, in the case of the first examined example in FIG. 7, as the number of required signal wiring SG increases due to the alternate arrangement of signal wiring SG and ground wiring GR, the number of required ground wiring GR also increases accordingly. Therefore, the area of the region required to arrange the signal wiring ins the wiring substrate (corresponding to the above wiring regions RG1, RG2) increases. This leads to an increase in the plan dimensions (plan area) of the semiconductor device connecting the signal wiring, and further, an increase in the plan dimensions of the wiring substrate.

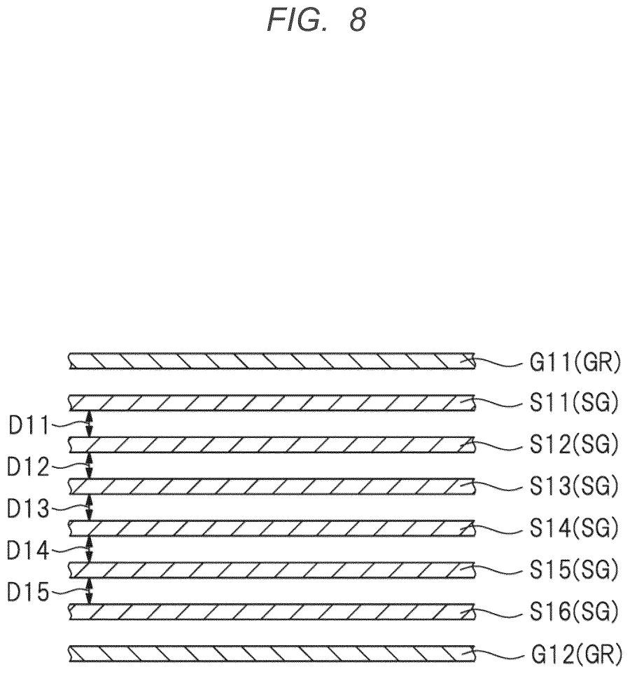

FIG. 8 is a plan view of the main portion of the wiring substrate of the second examined example studied by the present inventor, corresponding to FIGS. 3, 4, 5, and 6 of the present embodiment.

In the case of the second examined example in FIG. 8, the plurality (six in this case) of signal wirings S11, S12, S13, S14, S15, S16 are arranged at equal intervals between the two ground wirings G11, G12. That is, in the case of the second examined example in FIG. 8, the distance D11 between the signal wiring S11 and the signal wiring S12, the distance D12 between the signal wiring S12 and the signal wiring S13, the distance D13 between the signal wiring S13 and the signal wiring S14, the distance D14 between the signal wiring S14 and the signal wiring S15, and the distance D15 between the signal wiring S15 and the signal wiring S16 are all the same as each other. In other words, “D11=D12=D13=D14=D15” holds. No ground wiring is arranged between the signal wirings S11, S12, S13, S14, S15, S16.

In the case of the second examined example in FIG. 8, by arranging the signal wirings S11, S12, S13, S14, S15, S16 between the two ground wirings G11, G12, and not arranging a ground wiring between the signal wirings S11, S12, S13, S14, S15, S16, even if the number of required signal wirings SG increases, the number of required ground wirings GR can be suppressed. Therefore, the area of the region required to arrange the signal wiring in the wiring substrate (corresponding to the above wiring regions RG1, RG2) can be suppressed.

Furthermore, in the case of the second examined example in FIG. 3, by arranging the signal wirings S11, S12, S13, S14, S15, S16 at equal intervals, it becomes easier to suppress crosstalk occurring between adjacent signal wirings in the signal wirings S11, S12, S13, S14, S15, S16. This is because the magnitude of the crosstalk occurring between adjacent signal wirings depends on the distance between the adjacent signal wirings, and the smaller the distance between the adjacent signal wirings, the greater the crosstalk occurring between the adjacent signal wirings. If the distance between the ground wiring G11 and the ground wiring G12 does not change, making the distances D11, D12, D13, D14, D15 the same as each other can maximize the minimum distance in adjacent signal wirings S11, S12, S13, S14, S15, S16. As a result, it is possible to equalize the magnitude of the crosstalk occurring between adjacent signal wirings in the signal wirings S11, S12, S13, S14, S15, S16, and prevent the crosstalk from becoming large in a specific signal wiring.

However, according to the study by the present inventor, in the case of the second examined example in FIG. 8, each of the signal wirings S11, S12, S13, S14, S15, S16 arranged at equal intervals is easy to suppress the influence of crosstalk from one adjacent signal wirings, but there is a high risk of timing variation (variation in signal timing) due to the influence of crosstalk from two or more adjacent signal wirings. This will be explained below.

The wiring arrangement of the second examined example in the aforementioned FIG. 8 is considered to be a preferable wiring arrangement when all signal wirings S11, S12, S13, S14, S15, S16 is moving asynchronously and randomly. However, in reality, the signals propagated through the signal wirings are synchronous signals synchronized with the clock. In signal wiring, it is more important to suppress timing variations caused by crosstalk than to suppress the magnitude of crosstalk itself. In other words, if it is possible to suppress timing variations caused by crosstalk, there is no need to suppress the magnitude of crosstalk itself.

Therefore, the present inventors have considered minimizing the timing variations caused by crosstalk, not minimizing crosstalk itself, for synchronous signals.

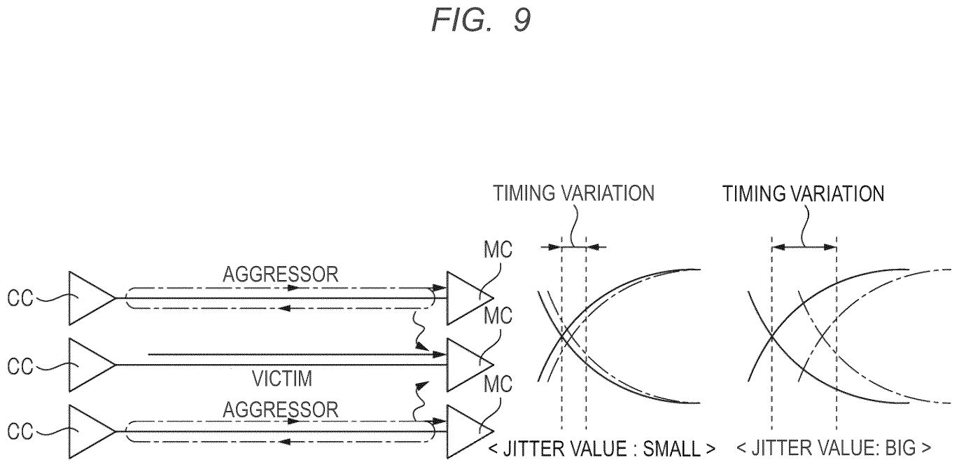

FIG. 9 is an explanatory diagram for explaining timing variations caused by crosstalk. In FIG. 9, the victim signal is indicated by a solid line, and the aggressor signal is indicated by a dotted chain line. In FIG. 9, the symbol CC is an input/output circuit of a semiconductor control device, and the symbol MC is an input/output circuit of a DRAM (semiconductor memory device).

When the aggressor signal (dotted chain line) causes a 0/1 transition to the victim signal (solid line), a certain proportion of the aggressor signal is added or subtracted to the victim signal as crosstalk at the timing of the 0/1 transition, thereby causing the victim signal voltage to fluctuate. At this time, if the voltage is fixed, the victim signal fluctuates in the time direction by the amount of B1/B2, inversely proportional to the slope B2 of the victim signal. This is the timing variation caused by crosstalk. Here, the above-mentioned B1 is a victim signal voltage variation caused by crosstalk.

As the victim signal undergoes a 0/1 transition, the slope of the victim signal inevitably becomes maximum at the 0/1 transition point of the victim signal, and decreases as it moves away from the 0/1 transition point of the victim signal.

Therefore, the timing variation per crosstalk voltage is minimized when the timing of the 0/1 transition of the victim signal and the timing of the 0/1 transition of the aggressor signal coincide. In other words, the smaller the skew between the victim signal and the aggressor signal, the smaller the timing variation per crosstalk voltage.

In other words, if the timing of the crosstalk generated from the aggressor signal coincides with the timing of the 0/1 transition of the victim signal, the timing variation (time direction variation) of the victim signal caused by the crosstalk is small. And, the larger the deviation between the timing of the crosstalk generated from the aggressor signal and the timing of the 0/1 transition of the victim signal, the larger the timing variation (time direction variation) of the victim signal caused by the crosstalk. The timing of the crosstalk generated from the aggressor signal coincides with the timing of the 0/1 transition of the aggressor signal. Therefore, if the skew between the victim signal and the aggressor signal is zero, the timing variation (time direction variation) of the victim signal caused by the crosstalk is small, but the larger the skew between the victim signal and the aggressor signal, the larger the timing variation (time direction variation) of the victim signal caused by the crosstalk. Therefore, it is understood that the timing variation per crosstalk voltage is small among signals with small skew.

Therefore, it is important which the signal wirings on the wiring substrate transmit signals with small skew. In a wiring substrate, there is a high probability that the skew of the transmitted signal is small between adjacent signal wirings. The reason is as follows.

The plurality of terminals of a semiconductor control device and the plurality of terminals of a semiconductor memory device are electrically connected via the plurality of signal wirings, and signals are transmitted between the semiconductor control device and the semiconductor memory device through these signal wirings. When considering the arrangement of multiple bus-type signal wirings, the order of the signal wirings is not randomly determined. Adjacent signal wirings are likely to be connected to adjacent terminals in the semiconductor control device and to adjacent terminals in the semiconductor memory device. In addition, adjacent signal wirings are likely to have similar characteristic impedances. Therefore, the skew of the transmitted signal is likely to be small between adjacent signal wirings. On the other hand, the skew of the transmitted signal is likely to be large between signal wirings that have one or more other signal wirings in between.

For example, in the second examined example in FIG. 8, focus on the signal wiring S11. The skew of the signal transmitted on the signal wiring S11 and the signal transmitted on the signal wiring S12 is likely to be small. In contrast, the skew of the signal transmitted on the signal wiring S11 and the signal transmitted on the signal wiring S13 is large, the skew of the signal transmitted on the signal wiring S11 and the signal transmitted on the signal wiring S14 is even larger, and the skew of the signal transmitted on the signal wiring S11 and the signal transmitted on the signal wiring S15 is even larger.

In the second examined example in FIG. 8, timing variations in the signal transmitted on the signal wiring S11 may occur due to crosstalk from the signal wirings S12, S13, S14, S15, S16. As mentioned above, since the skew of the transmitted signal is likely to be small between adjacent the signal wirings, timing variations are unlikely to occur in the signal transmitted on the signal wiring S11 due to crosstalk from the signal wiring S12. However, in the case of the second examined example in FIG. 8, it is a concern that timing variations may occur in the signal transmitted on the signal wiring S11 due to crosstalk from the signal wirings S13, S14, S15, S16. On the other hand, in the second examined example in FIG. 8, if we focus on the signal wiring S12, timing variations are unlikely to occur in the signal transmitted on the signal wiring S12 due to crosstalk from the signal wirings S11, S13. However, it is a concern that timing variations may occur in the signal transmitted on the signal wiring S12 due to crosstalk from the signal wirings S14, S15, S16. The same can be considered for timing variations in the signals transmitted on other signal wirings S13, S14, S15, S16.

Timing variations in the signal transmitted on the signal wiring due to crosstalk can lead to a decrease in the performance of the electronic device, so it is necessary to suppress them.

### <MAIN FEATURES AND EFFECTS>

The electronic device DS of the present embodiment is equipped with a wiring substrate PB, a semiconductor memory device MD arranged on the wiring substrate PB, and a semiconductor control device CD arranged on the wiring substrate PB and controlling the semiconductor device MD. The wiring substrate PB has ground wirings G1, G2 which are fixed potential wires, and the plurality of signal wirings SG arranged between the ground wirings G1, G2 in plan view and transmitting signals between the semiconductor device CD and the semiconductor device MD. The plurality of signal wirings SG arranged between the ground wirings G1, G2 include a signal wiring S1 adjacent to the ground wiring G1, a signal wiring S2 adjacent to the signal wiring S1, and a signal wiring S3 adjacent to the signal wiring S2. In plan view, the signal wiring S1 is arranged between the signal wiring S2 and the ground wiring G1, and the signal wiring S2 is arranged between the signal wiring S3 and the signal wiring S1.

One of the main features of the present embodiment is that the distance D1 between the signal wiring S1 and the signal wiring S2 is smaller than the distance D2 between the signal wiring S2 and the signal wiring S3 (“D1<D2”) (refer to FIGS. 3, 4, 5, and 6).

Assuming a case where the signal wirings S1, S2, and S3 are arranged at equal intervals, which is different from the present embodiment. In this case, as explained in relation to the second examined example in FIG. 8, it is easy to suppress the crosstalk between the signal wiring S1 and the signal wiring S2, and the crosstalk between the signal wiring S2 and the signal wiring S3, but there is a concern that timing fluctuations may occur in the signals transmitted through the signal wirings S1 and S3 due to the crosstalk between them.

In contrast, in the present embodiment, the distance D1 between the signal wiring S1 and the signal wiring S2 is made smaller than the distance D2 between the signal wiring S2 and the signal wiring S3 (i.e., “D1<D2”). By reducing the distance D1 between the signal wiring S1 and the signal wiring S2, the electromagnetic coupling between the signal wiring S1 and the signal wiring S2 becomes stronger, and the pair of the signal wiring S1 and the signal wiring S2 becomes less susceptible to crosstalk from other signal wirings SG (S3). Therefore, it is possible to suppress timing fluctuations in signals transmitted through the signal wirings S1, S2, and S3 due to the crosstalk between the signal wiring S1 and the signal wiring S3, and the crosstalk between the signal wiring S2 and the signal wiring S3. It is preferable that the signal wirings S1 and S2 have the same length and the same characteristic impedance.

On the other hand, in the present embodiment, by reducing the distance D1 between the signal wiring S1 and the signal wiring S2, the crosstalk between the signal wiring S1 and the signal wiring S2 itself may increase. However, since the signal wiring S1 and the signal wiring S2 are adjacent to each other, the skew of the signals transmitted through the signal wiring S1 and the signal wiring S2 is likely to be small. Therefore, the risk of timing fluctuations occurring in the signals transmitted through the signal wirings S1 and S2 due to the crosstalk between them is small.

Therefore, by making the distance D1 between the signal wiring S1 and the signal wiring S2 smaller than the distance D2 between the signal wiring S2 and the signal wiring S3 (“D1<D2”), it is possible to suppress timing fluctuations in the signals transmitted through the signal wirings S1, S2, and S3 due to crosstalk.

In FIGS. 4, 5, and 6, the plurality of signal wirings SG arranged between the ground wirings G1 and G2 include the signal wiring S3 and the adjacent signal wiring S4. The distance D3 between the signal wiring S3 and the signal wiring S4 is made smaller than the distance D2 between the signal wiring S2 and the signal wiring S3 (“D3<D2”). It is preferable that the distance D1 between the signal wiring S1 and the signal wiring S2 and the distance D3 between the signal wiring S3 and the signal wiring S4 are the same (D1=D3).

By reducing the distance D3 between the signal wiring S3 and the signal wiring S4, the electromagnetic coupling between the signal wiring S3 and the signal wiring S4 becomes stronger, and the pair of the signal wiring S3 and the signal wiring S4 becomes less susceptible to crosstalk from other signal wirings SG (S1, S2). Therefore, it is possible to suppress timing fluctuations in the signals transmitted through the signal wirings S1, S2, S3, and S4 due to the crosstalk between the signal wiring S1 and the signal wiring S3, the crosstalk between the signal wiring S1 and the signal wiring S4, the crosstalk between the signal wiring S2 and the signal wiring S3, and the crosstalk between the signal wiring S2 and the signal wiring S4. It is preferable that the signal wirings S3 and S4 have the same length and the same characteristic impedance.

On the other hand, by reducing the distance D3 between the signal wiring S3 and the signal wiring S4, the crosstalk between the signal wiring S3 and the signal wiring S4 itself may increase. However, since signal wirings S3 and S4 are adjacent to each other, the skew of the signals transmitted through signal wirings S3 and S4 is likely to be small. Therefore, the risk of timing fluctuations occurring in the signals transmitted through signal wirings S3 and S4 due to crosstalk between signal wirings S3 and S4 is small.

Therefore, it is possible to suppress the occurrence of timing fluctuations in the signals transmitted through signal wirings S1, S2, S3, and S4 due to crosstalk.

In FIGS. 5 and 6, the plurality of signal wirings SG arranged between ground wirings G1 and G2 further include signal wiring S4 and adjacent signal wiring S5. The distance D4 between signal wirings S4 and S5 is larger than the distance D1 between signal wirings S1 and S2 (“D4>D1”), and also larger than the distance D3 between signal wirings S3 and S4 (“D4>D3”). It is preferable that the distances D1 and D3 are the same (“D1=D3”). It is preferable that the distances D2 and D4 are the same (“D2=D4”).

By increasing the distance D4 between signal wirings S4 and S5, the pairs of signal wirings S1 and S2, and signal wirings S3 and S4, become less susceptible to crosstalk from signal wiring S5. Therefore, it is possible to suppress the occurrence of timing fluctuations in the signals transmitted through signal wirings S1, S2, S3, S4, and S5 due to crosstalk between signal wirings S1 and S5, signal wirings S2 and S5, signal wirings S3 and S5, and signal wirings S4 and S5.

Therefore, it is possible to suppress the occurrence of timing fluctuations in the signals transmitted through signal wirings S1, S2, S3, S4, and S5 due to crosstalk.

In FIG. 6, in the present embodiment, the plurality of signal wirings SG arranged between ground wirings G1 and G2 further include signal wiring S5 and adjacent signal wiring S6. The distance DS between signal wirings S5 and S6 is smaller than the distance D2 between signal wirings S2 and S3 (“D5<D2”), and also smaller than the distance D4 between signal wirings S4 and S5 (“D5<D4”). It is preferable that the distances D1, D3, and D5 are the same (“D1=D3=D5”). It is preferable that the distances D2 and D4 are the same (“D2=D4”).

As a result, the electromagnetic coupling between signal wirings S5 and S6 becomes stronger, and the pair of signal wirings S5 and S6 becomes less susceptible to crosstalk from other signal wirings SG (S1, S2, S3, S4). Therefore, it is possible to suppress the occurrence of timing fluctuations in the signals transmitted through signal wirings S1, S2, S3, S4, S5, and S6 due to crosstalk between signal wirings S1 and S3, signal wirings S1 and S4, signal wirings S1 and S5, signal wirings S1 and S6, signal wirings S2 and S3, signal wirings S2 and S4, signal wirings S2 and S5, and signal wirings S2 and S6. Furthermore, it is possible to suppress the occurrence of timing fluctuations in the signals transmitted through signal wirings S1, S2, S3, S4, S5, and S6 due to crosstalk between signal wirings S3 and S5, signal wirings S3 and S6, signal wirings S4 and S5, and signal wirings S4 and S6. It should be noted that signal wirings S5 and S6 preferably have the same length and the same characteristic impedance.

On the other hand, by reducing the distance D5 between signal wirings S5 and S6, the crosstalk between signal wirings S5 and S6 itself may increase. However, since signal wirings S5 and S6 are adjacent to each other, the skew of the signals transmitted through signal wirings S5 and S6 is likely to be small. Therefore, the risk of timing fluctuations occurring in the signals transmitted through signal wirings S5 and S6 due to crosstalk between signal wirings S5 and S6 is small.

Therefore, it is possible to suppress the occurrence of timing fluctuations in the signals transmitted through signal wirings S1, S2, S3, S4, S5, and S6 due to crosstalk.

In this way, in the present embodiment, it is possible to suppress timing fluctuations in the signal transmitted through the signal wiring due to crosstalk, thereby improving the performance of the electronic device.

In the present embodiment, a plurality of signal wirings SG is arranged between the ground wiring G1 and the ground wiring G2, and no ground wirings are arranged between these signal wirings SG. As a result, even if the number of necessary signal wirings SG increases, the number of necessary ground wirings GR can be suppressed. Therefore, it is possible to suppress the area of the region (corresponding to the wiring regions RG1, RG2) necessary for arranging the signal wirings on the wiring substrate. Therefore, it is possible to achieve both improvement in the performance of the electronic device and miniaturization of the electronic device.

Each of the intervals D1, D3, D5 is smaller than each of the intervals D2, D4. Therefore, the intervals D1, D3, D5 can be considered as small wiring intervals, and the intervals D2, D4 can be considered as large wiring intervals. In the present embodiment, a plurality of signal wirings SG is arranged between the ground wiring G1 and the ground wiring G2, alternating between small wiring intervals and large wiring intervals. Therefore, as a modified example in FIG. 6, when arranging a further signal wiring S7 (not shown) between the signal wiring S6 and the ground wiring G2, the interval between the signal wiring S7 and the signal wiring S6 should be set to the same large wiring interval as the intervals D2, D4. When arranging a further signal wiring S8 (not shown) between the signal wiring S7 and the ground wiring G2, the interval between the signal wiring S8 and the signal wiring S7 should be set to the same small wiring interval as the intervals D1, D3, D5. The same can be considered when adding more signal wirings.

In the present embodiment, the signal wiring SG applying the technical concept of the present embodiment is a single-ended type signal wiring, and it is preferable to be a single-ended type data signal wiring. The data signal transmitted through the data signal wiring is higher in frequency than the command address signal and the clock signal.

In the present embodiment, the plurality of signal wirings SG is arranged between two fixed potential wirings, and these signal wirings SG are shielded, and the ground wirings G1 and G2 are used as the two fixed potential wirings. The ground wirings G1 and G2 are a fixed potential wiring onto which a ground potential is to be supplied, and the potentials of each of the ground wirings G1 and G2 are fixed at the ground potential. As a modified example, it is also possible to use a fixed potential wiring onto which a fixed potential (power supply potential) other than the ground potential is to be supplied, instead of the ground wirings G1 and G2. That is, the plurality of signal wirings SG can be arranged between two fixed potential wirings onto which a fixed potential other than the ground potential is to be supplied, and the distances between these signal wirings SG can be set as described above. In that case, the fixed potentials supplied to each of the two fixed potential wirings are the same as each other.

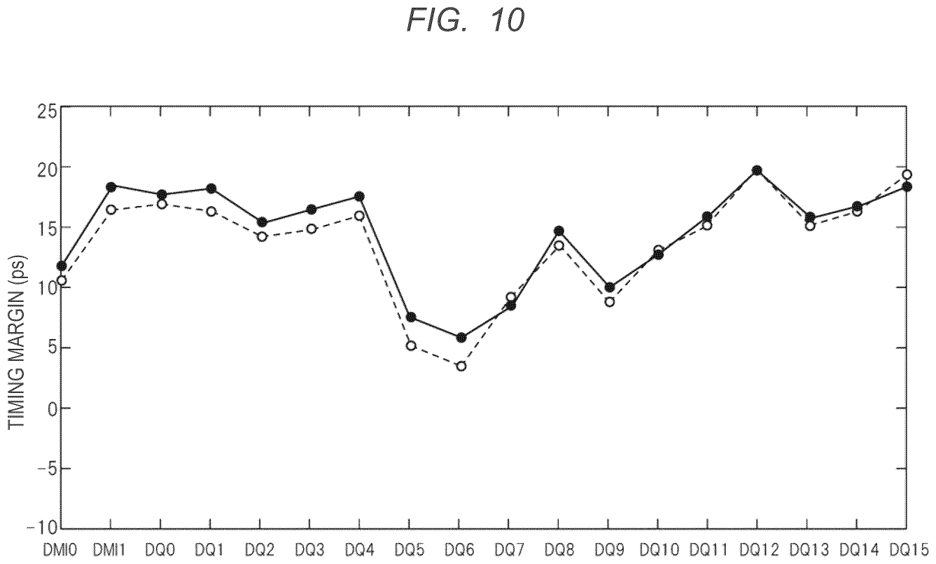

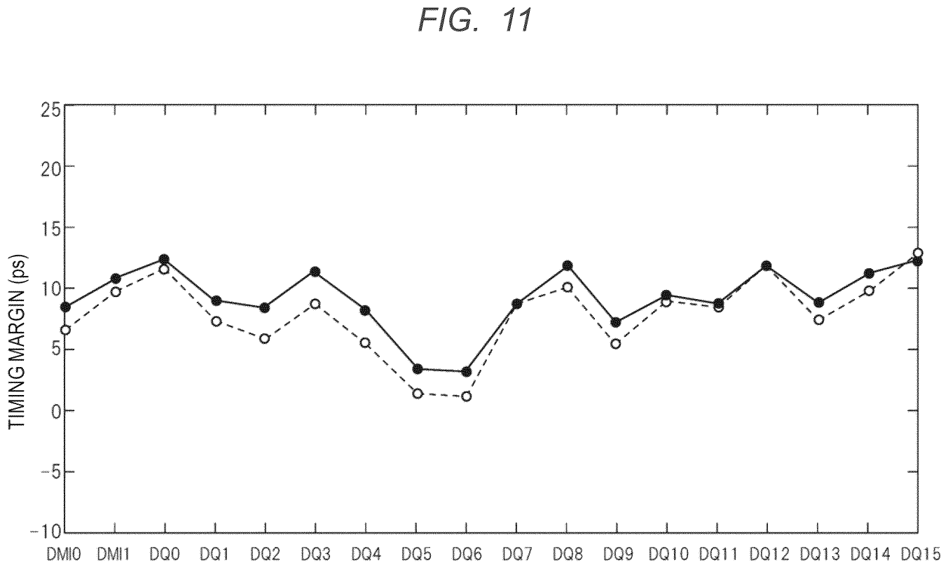

FIG. 10 is a graph showing an example of a timing margin when a write operation to a semiconductor memory device is performed by a semiconductor control device. FIG. 11 is a graph showing an example of a timing margin when a read operation from a semiconductor memory device is performed by a semiconductor control device. The timing margin is one of the indicators for evaluating the magnitude of timing fluctuations occurring in the signal transmitted through the signal wiring. The larger the timing margin, the smaller the timing fluctuation occurring in the signal transmitted through the signal wiring.

In each of FIGS. 10 and 11, the case where the wiring arrangement of the present embodiment as shown in FIGS. 3, 4, 5 and 6 is applied is shown by a solid line, and the case where the wiring arrangement like the second examined example shown in FIG. 8 is applied is shown by a dotted line.

In each of FIGS. 10 and 11, the timing margin is larger in the solid line graph (present embodiment) than in the dotted line graph (second examined example). From this, it can be seen that compared to the case where the plurality of signal wirings is arranged at equal intervals between the ground wirings G11 and G12 as in the second examined example shown in FIG. 8, by arranging the plurality of signal wirings SG alternately with small wiring intervals and large wiring intervals between the ground wirings G1 and G2 as in the present embodiment, the timing fluctuation occurring in the signal transmitted through the signal wiring can be suppressed.

### Second Embodiment

In the first embodiment, the way of setting the wiring intervals of the plurality of single-ended signal wirings SG arranged between the ground wirings G1 and G2 was explained.

In the second embodiment, it will be explained when the plurality of signal wirings SG arranged between the ground wirings G1 and G2 are not single-ended type but differential type signal wirings. In the case of differential type signal wiring, the differential signal pair is considered as one signal, and the signal wiring is arranged according to the rule of the first embodiment.

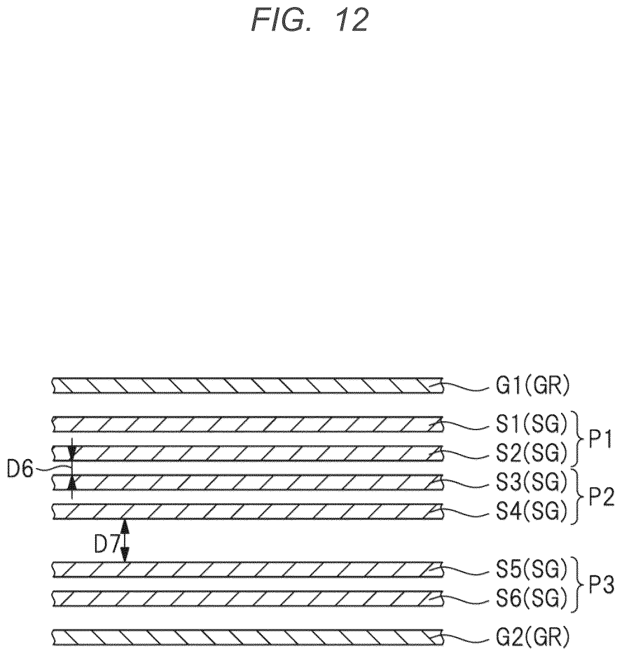

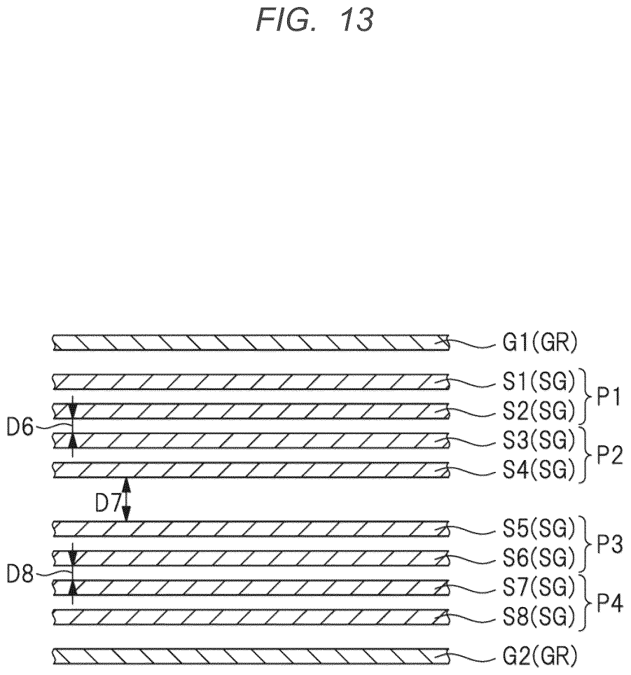

Each of FIGS. 12 and 13 is a partial enlarged view showing an enlarged part of the wiring region RG1 or the wiring region RG2 shown in FIG. 1.

The technical concept of the first embodiment is to arrange three or more single-ended signal wirings between the ground wiring G1 and the ground wiring G2, and to arrange these three or more single-ended signal wirings alternately with small wiring intervals and larger wiring intervals.

On the other hand, the technical concept of the second embodiment involves arranging three or more differential pairs between the ground wiring G1 and the ground wiring G2, and arranging these three or more differential pairs in a pattern that alternates between smaller intervals and larger intervals. This is because a pair of signal wirings (differential pair) functions as an equivalent signal wiring to a single-ended signal wiring. The aforementioned smaller interval and larger interval are each the interval between two adjacent differential pairs. FIGS. 12 and 13 follow this technical concept, but the number of differential pairs arranged between the ground wiring G1 and the ground wiring G2 differs between FIGS. 12 and 13. In the case of FIG. 12, the number of differential pairs arranged between the ground wirings G1 and G2 is three, while in the case of FIG. 13, the number is four.

FIG. 12 shows two ground wirings GR and six signal wirings SG arranged between the two ground wirings GR in a plan view. FIG. 13 shows two ground wirings GR and eight signal wirings SG arranged between the two ground wirings GR in a plan view. Similar to the first embodiment, in the second embodiment, each signal wiring SG electrically connects the semiconductor device CD and the semiconductor device MD, and functions as a signal wiring transmitting signals between the semiconductor device CD and the semiconductor device MD.

However, in the second embodiment, each signal wiring SG shown in FIGS. 12 and 13 is not a single-ended signal wiring, but a differential signal wiring, and a differential pair is formed by two adjacent signal wirings SG.

Also in the second embodiment, in each of FIGS. 12 and 13, one of the two ground wirings GR is referred to as a ground wiring G1, and the other is referred to as a ground wiring G2. In FIG. 12, the six signal wirings SG arranged between the ground wiring G1 and the ground wiring G2 are referred to in order from the direction from the ground wiring G1 to the ground wiring G2 as a signal wiring S1, signal wiring S2, signal wiring S3, signal wiring S4, signal wiring S5, and signal wiring S6. In FIG. 13, the eight signal wirings SG arranged between the ground wiring G1 and the ground wiring G2 are referred to in order from the direction from the ground wiring G1 to the ground wiring G2 as the signal wiring S1, the signal wiring S2, the signal wiring S3, the signal wiring S4, the signal wiring S5, the signal wiring S6, the signal wiring S7, and the signal wiring S8.

In the case of FIG. 12, the ground wiring G1, the signal wiring S1, the signal wiring S2, the signal wiring S3, the signal wiring S4, the signal wiring S5, the signal wiring S6, and the ground wiring G2 are formed in the same layer (same wiring layer) on the wiring substrate PB and, in a plan view, they are arranged and run parallel in this order. In the case of FIG. 13, the ground wiring G1, the signal wiring S1, the signal wiring S2, the signal wiring S3, the signal wiring S4, the signal wiring S5, the signal wiring S6, the signal wiring S7, the signal wiring SS, and the ground wiring G2 are formed in the same layer (same wiring layer) on the wiring substrate PB and, in a plan view, they are arranged and run parallel in this order.

In each of FIGS. 12 and 13, the ground wiring G1 and the signal wiring S1 are adjacent to each other, the signal wiring S1 and the signal wiring S2 are adjacent to each other, the signal wiring S2 and the signal wiring S3 are adjacent to each other, the signal wiring S3 and the signal wiring S4 are adjacent to each other, the signal wiring S4 and the signal wiring S5 are adjacent to each other, and the signal wiring S5 and the signal wiring S6 are adjacent to each other. In each of FIGS. 12 and 13, the signal wiring S1 is arranged between the ground wiring G1 and the signal wiring S2, the signal wiring S2 is arranged between the signal wirings S1 and S3, the signal wiring S3 is arranged between the signal wirings S2 and S4, the signal wiring S4 is arranged between the signal wirings S3 and S5, and the signal wiring S5 is arranged between the signal wirings S4 and S6.

In FIG. 12, the signal wiring S6 and the ground wiring G2 are adjacent to each other, and the signal wiring S6 is arranged between the signal wiring S5 and the ground wiring G2.

In FIG. 13, the signal wirings S6 and S7 are adjacent to each other, the signal wirings S7 and S8 are adjacent to each other, and the signal wiring S8 and the ground wiring G2 are adjacent to each other. In FIG. 13, the signal wiring S6 is arranged between the signal wirings S5 and S7, the signal wiring S7 is arranged between the signal wirings S6 and S8, and the signal wiring S8 is arranged between the signal wiring S7 and the ground wiring G2.

In each of FIGS. 12 and 13, no ground wirings are arranged between the plurality of signal wirings SG arranged between the ground wirings G1 and G2.

In the case of FIG. 12, a differential pair P1 is formed by a signal wiring S1 and a signal wiring S2, a differential pair P2 is formed by a signal wiring S3 and a signal wiring S4, and a differential pair P3 is formed by a signal wiring S5 and a signal wiring S6. In the case of FIG. 13, a differential pair P1 is formed by a signal wiring S1 and a signal wiring S2, a differential pair P2 is formed by a signal wiring S3 and a signal wiring S4, a differential pair P3 is formed by a signal wiring S5 and a signal wiring S6, and a differential pair P4 is formed by a signal wiring S7 and a signal wiring S8.

In each of FIGS. 12 and 13, the differential pair P1 is adjacent to the ground wiring G1, the differential pair P2 is adjacent to the differential pair P1, and the differential pair P3 is adjacent to the differential pair P2. In each of FIGS. 12 and 13, the differential pair P1 is arranged between the differential pair P2 and the ground wiring G1, and the differential pair P2 is arranged between the differential pair P3 and the differential pair P1. In FIG. 12, the ground wiring G2 is adjacent to the differential pair P3, and the differential pair P3 is arranged between the ground wiring G2 and the differential pair P2.

In FIG. 13, the differential pair P4 is adjacent to the differential pair P3, and the ground wiring G2 is adjacent to the differential pair P4. In FIG. 13, the differential pair P3 is arranged between the differential pair P4 and the differential pair P2, and the differential pair P4 is arranged between the ground wiring G2 and the differential pair P3.

In each of FIGS. 12 and 13, the distance D6 between the differential pairs P1 and P2 is smaller than the distance D7 between the differential pairs P2 and P3 (i.e., “D6<D7”). In FIG. 13, the distance D8 between the differential pairs P3 and P4 is smaller than the distance D7 between the differential pairs P2 and P3 (i.e., “D8<D7”). It is preferable that the distance D8 between the differential pairs P3 and P4 is the same as the distance D6 between the differential pairs P1 and P2 (i.e., “D6=D8”).

The distance D6 between the differential pair P1 and the differential pair P2 is the distance between the signal wiring S2 constituting the differential pair P1 and the signal wiring S3 constituting the differential pair P2. The distance D7 between the differential pair P2 and the differential pair P3 is the distance between the signal wiring S4 constituting the differential pair P2 and the signal wiring S5 constituting the differential pair P3. The distance D8 between the differential pair P3 and the differential pair P4 is the distance between the signal wiring S6 constituting the differential pair P3 and the signal wiring S7 constituting the differential pair P4.

When applying the technical idea of the first embodiment to the present embodiment 2, the differential pair P1 in the present embodiment 2 corresponds to the single-ended signal wiring S1 in the first embodiment. The differential pair P2 in the present embodiment 2 corresponds to the single-ended signal wiring S2 in the first embodiment. The differential pair P3 in the present embodiment 2 corresponds to the single-ended signal wiring S3 in the first embodiment. In the second embodiment, the differential pair P4 corresponds to the single-ended signal wiring S4 in the first embodiment.

Therefore, in the first embodiment, making the distance D1 between the signal wiring S1 and the signal wiring S2 smaller than the distance D2 between the signal wiring S2 and the signal wiring S3 (“D1<D2”) corresponds to making the distance D6 between the differential pair P1 and the differential pair P2 smaller than the distance D7 between the differential pair P2 and the differential pair P3 (“D6<D7”) in the second embodiment. Making the distance D3 between the signal wiring S3 and the signal wiring S4 smaller than the distance D2 between the signal wiring S2 and the signal wiring S3 (“D3<D2”) in the first embodiment corresponds to making the distance DS between the differential pair P3 and the differential pair P4 smaller than the distance D7 between the differential pair P2 and the differential pair P3 (“D8<D7”) in the second embodiment.

Assuming a case where the differential pairs P1, P2, and P3 are arranged at equal intervals, which is different from the second embodiment. In this case, it is easy to suppress the crosstalk between the differential pair P1 and the differential pair P2, and the crosstalk between the differential pair P2 and the differential pair P3, but there is a concern that timing variations may occur in the signals transmitted by the differential pairs P1 and P3 due to the crosstalk between them.

In contrast, in the second embodiment, the distance D6 between the differential pair P1 and the differential pair P2 is made smaller than the distance D7 between the differential pair P2 and the differential pair P3 (“D6<D7”) (see FIGS. 12 and 13). By reducing the distance D6 between the differential pair P1 and the differential pair P2, the electromagnetic coupling between the differential pair P1 and the differential pair P2 becomes stronger, and the pair of the differential pair P1 and the differential pair P2 becomes less susceptible to crosstalk from other differential pairs (P3). Therefore, it is possible to suppress the occurrence of timing variations in the signals transmitted by the differential pairs P1, P2, and P3 due to the crosstalk between the differential pair P1 and the differential pair P3, and the crosstalk between the differential pair P2 and the differential pair P3.

On the other hand, in the second embodiment, by reducing the distance D6 between the differential pair P1 and the differential pair P2, the crosstalk between the differential pair P1 and the differential pair P2 itself may increase. However, since the differential pair P1 and the differential pair P2 are adjacent to each other, the skew of the signal transmitted by the differential pair P1 and the signal transmitted by the differential pair P2 is likely to be small. Therefore, the risk of timing variations occurring in the signals transmitted by the differential pairs P1 and P2 due to the crosstalk between them is small.

Therefore, by making the distance D6 between the differential pair P1 and the differential pair P2 smaller than the distance D7 between the differential pair P2 and the differential pair P3 (“D6<D7”), it is possible to suppress the occurrence of timing variations in the signals transmitted by the differential pairs P1, P2, and P3 due to crosstalk.

In FIG. 13, the differential pair P4 is arranged between the ground wirings G1 and G2, adjacent to the differential pair P3. The distance D8 between the differential pair P3 and the differential pair P4 is made smaller than the distance D7 between the differential pair P2 and the differential pair P3 (“D8<D7”). It is preferable that the distance D8 between the differential pair P3 and the differential pair P4 is the same as the distance D6 between the differential pair P1 and the differential pair P2 (“D6=D8”).

By reducing the distance D8 between the differential pair P3 and the differential pair P4, the electromagnetic coupling between the differential pair P3 and the differential pair P4 becomes stronger, and the pair of the differential pair P3 and the differential pair P4 becomes less susceptible to crosstalk from other differential pairs (P1, P2). Therefore, it is possible to suppress the occurrence of timing variations in the signals transmitted by the differential pairs P1, P2, P3, and P4 due to the crosstalk between the differential pair P1 and the differential pair P3, the crosstalk between the differential pair P1 and the differential pair P4, the crosstalk between the differential pair P2 and the differential pair P3, and the crosstalk between the differential pair P2 and the differential pair P4.

On the other hand, by reducing the distance D8 between the differential pair P3 and the differential pair P4, the crosstalk between the differential pair P3 and the differential pair P4 itself may increase. However, since the differential pairs P3 and P4 are adjacent to each other, the skew of the signals transmitted to the differential pairs P3 and P4 is likely to be small. Therefore, the risk of timing variations occurring in the signals transmitted to the differential pairs P3 and P4 due to crosstalk between the differential pairs P3 and P4 is small. Therefore, it is possible to suppress the occurrence of timing variations in the signals transmitted to the differential pairs P1, P2, P3, and P4 due to crosstalk.

In this way, in the second embodiment, it is possible to suppress the occurrence of timing variations in the signals transmitted to the signal wiring due to crosstalk, thereby improving the performance of the electronic device.

As in the first embodiment, in the second embodiment, the plurality of signal wirings SG is arranged between the ground wirings G1 and G2, and no ground wiring is arranged between the plurality of signal wirings SG. This allows the number of necessary ground wirings GR to be suppressed even if the number of necessary signal wirings SG increases. Therefore, it is possible to suppress the area of the region required to arrange the signal wirings in the wiring substrate (corresponding to the wiring regions RG1 and RG2). Therefore, it is possible to achieve both improvement in the performance of the electronic device and miniaturization of the electronic device.

Each of the distances D6 and D8 is smaller than the distance D7. Therefore, the distances D6 and D8 can be considered as a small distance, and the distance D7 can be considered as a large distance. In the second embodiment, the plurality of differential pairs is arranged by alternately repeating the small distance and the large distance between the ground wirings G1 and G2. Note that each of the small distance and the large distance is a distance between two adjacent differential pairs. Therefore, as a modified example in FIG. 13, when arranging a further differential pair P5 (not shown) between the differential pair P4 and the ground wiring G2, the distance between the differential pair P5 and the differential pair P4 may be set to the same large interval as the distance D7. When arranging a further differential pair P6 (not shown) between the differential pair P5 and the ground wiring G2, the distance between the differential pair P6 and the differential pair P5 may be set to the same small distance as the distances D6 and D8. The same can be considered even when adding more differential pairs.

The signal wiring SG to which the technical idea of the second embodiment is applied is a differential signal wiring, but it is preferable that it is a differential data signal wiring. As in the first embodiment, in the second embodiment, a fixed potential line that supplies a fixed potential other than the ground potential (power supply potential) can also be used instead of the ground wirings G1 and G2.

Although the invention made by the present inventor has been specifically described based on the embodiments, it goes without saying that the present invention is not limited to the embodiments and can be variously modified without departing from the spirit thereof.

What is claimed is:

1. An electronic device comprising:
a wiring substrate;
a first semiconductor device disposed on the wiring substrate; and
a second semiconductor device disposed on the wiring substrate and controlling the first semiconductor device,
wherein the wiring substrate includes:
a first fixed potential wiring;
a second fixed potential wiring; and
a plurality of signal wirings arranged between the first fixed potential wiring and the second fixed potential wiring in plan view, the plurality of signal wirings being a wiring for transmitting a signal between the first semiconductor device and the second semiconductor device, wherein the plurality of signal wirings includes:
a first signal wiring adjacent to the first fixed potential wiring;
a second signal wiring adjacent to the first signal wiring; and
a third signal wiring adjacent to the second signal wiring,
wherein the first signal wiring is arranged between the second signal wiring and the first fixed potential wiring,
wherein the second signal wiring is arranged between the third signal wiring and the first signal wiring, and
wherein a first distance between the first signal wiring and the second signal wiring is smaller than a second distance between the second signal wiring and the third signal wiring.

2. The electronic device according to claim 1, wherein the third signal wiring and the second fixed potential wiring are adjacent to each other.

3. The electronic device according to claim 1,
wherein the plurality of signal wirings further includes a fourth signal wiring adjacent to the third signal wiring,
wherein the third signal wiring is arranged between the fourth signal wiring and the second signal wiring, and
wherein a third distance between the third signal wiring and the fourth signal wiring is smaller than the second distance.

4. The electronic device according to claim 3, wherein the first distance and the third distance are the same as each other.

5. The electronic device according to claim 4, wherein the fourth signal wiring and the second fixed potential wiring are adjacent to each other.

6. The electronic device according to claim 3,
wherein the plurality of signal wirings further includes a fifth signal wiring adjacent to the fourth signal wiring,
wherein the fourth signal wiring is arranged between the fifth signal wiring and the third signal wiring, and
wherein a fourth distance between the fourth signal wiring and the fifth signal wiring is larger than each of the first distance and the third distance.

7. The electronic device according to claim 6,
wherein the first distance and the third distance are the same as each other, and
wherein the second distance and the fourth distance are the same as each other.

8. The electronic device according to claim 7, wherein the fifth signal wiring and the second fixed potential wiring are adjacent to each other.

9. The electronic device according to claim 6,
wherein the plurality of signal wirings further includes a sixth signal wiring adjacent to the fifth signal wiring,
wherein the fifth signal wiring is arranged between the sixth signal wiring and the fourth signal wiring, and
wherein the fifth distance between the fifth signal wiring and the sixth signal wiring is smaller than each of the second distance and the fourth distance.

10. The electronic device according to claim 9,
wherein the first distance, the third distance and the fifth distance are the same as each other, and
wherein the second distance and the fourth distance are the same as each other.

11. The electronic device according to claim 10, wherein the sixth signal wiring and the second fixed potential wiring are adjacent to each other.

12. The electronic device according to claim 1, wherein each of the plurality of signal wirings is a wiring of a single-ended type.

13. An electronic device comprising:
a wiring substrate;
a first semiconductor device disposed on the wiring substrate; and
a second semiconductor device disposed on the wiring substrate and controlling the first semiconductor device,
wherein the wiring substrate includes:
a first fixed potential wiring;
a second fixed potential wiring; and
a plurality of signal wirings arranged between the first fixed potential wiring and the second fixed potential wiring in a plan view, the plurality of signal wirings being a wiring for transmitting a signal between the first semiconductor device and the second semiconductor device, wherein the plurality of signal wirings includes:
a first differential pair comprised of a first signal wiring and a second signal wiring, the first differential pair being adjacent to the first fixed potential wiring;
a second differential pair comprised of a third signal wiring and a fourth signal wiring, the second differential pair being adjacent to the first differential pair; and
a third differential pair comprised of a fifth signal wiring and a sixth signal wiring, the third differential pair being adjacent to the second differential pair,
wherein the first differential pair is arranged between the second differential pair and the first fixed potential wiring,
wherein the second differential pair is arranged between the third differential pair and the first differential pair, and
wherein a first distance between the first differential pair and the second differential pair is smaller than a second distance between the second differential pair and the third differential pair.

14. The electronic device according to claim 13, wherein the third differential pair and the second fixed potential wiring are adjacent to each other.

15. The electronic device according to claim 13,
wherein the plurality of signal wirings further includes a fourth differential pair comprised of a seventh signal wiring and an eighth signal wiring, the fourth differential pair being adjacent to the third differential pair,
wherein the third differential pair is arranged between the fourth differential pair and the second differential pair, and
wherein a third distance between the third differential pair and the fourth differential pair is smaller than the second distance.

16. The electronic device according to claim 15, wherein the first distance and the third distance are the same as each other.

17. The electronic device according to claim 16, wherein the fourth differential pair and the second fixed potential wiring are adjacent to each other.
